(19) United States
(12) Patent Application Publication
(10) Pub. No.: US 2025/0294972 A1
(43) Pub. Date: Sep. 18, 2025

(54) DISPLAY DEVICE

(71) Applicant: Japan Display Inc., Tokyo (JP)

(72) Inventors: Hiroshi TABATAKE, Tokyo (JP); Kaichi FUKUDA, Tokyo (JP)

(73) Assignee: Japan Display Inc., Tokyo (JP)

(21) Appl. No.: 19/073,048

(22) Filed: Mar. 7, 2025

(30) Foreign Application Priority Data
Mar. 14, 2024 (JP) 2024-039902

(51) Int. Cl. H10K 59/122

(52) U.S. Cl. CPC H10K 59/122

(57) ABSTRACT

According to one embodiment, a display device includes an organic insulating layer composed of an organic material, a first lower electrode provided above the organic insulating layer, an inorganic insulating layer composed of an inorganic material and provided between the organic insulating layer and the first lower electrode, and a rib layer overlapping the first lower electrode and having a first aperture, the inorganic insulating layer overlapping the first aperture in plan view.

### CROSS-REFERENCE TO RELATED APPLICATION

This application is based upon and claims the benefit of priority from Japanese Patent Application No. 2024-039902, filed Mar. 14, 2024, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. In this type of display devices, a technique which can suppress degradation in display quality is requested.

### BRIEF DESCRIPTION OF THE DRAWINGS

FIG. 1 is a view showing a configuration example of a display device DSP of a present embodiment.

FIG. 2 is a schematic plan view showing a layout example of subpixels SP1, SP2, and SP3.

FIG. 3 is a schematic plan view showing the subpixels SP1, SP2, and SP3 shown in FIG. 2 in an enlarged manner.

FIG. 4 is a schematic cross-sectional view showing the display device DSP along A-A′ line in FIG. 3.

FIG. 5 is a schematic plan view showing a vicinity of contact holes CH1 and CH2 shown in FIG. 3 in an enlarged manner.

FIG. 6 is a schematic cross-sectional view showing the display device DSP along B-B′ line in FIG. 5.

FIG. 7 is a schematic plan view showing a vicinity of a contact hole CH3 shown in FIG. 3 in an enlarged manner.

FIG. 8 is a schematic cross-sectional view showing the display device DSP along C-C′ line in FIG. 7.

### DETAILED DESCRIPTION

In general, according to one embodiment, a display device includes an organic insulating layer composed of an organic material, a first lower electrode provided above the organic insulating layer, an inorganic insulating layer composed of an inorganic material and provided between the organic insulating layer and the first lower electrode, and a rib layer overlapping the first lower electrode and having a first aperture, the inorganic insulating layer overlapping the first aperture in plan view.

Embodiments can provide a display device capable of suppressing degradation in display quality.

Embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X direction. A direction parallel to the Y-axis is referred to as a Y direction. A direction parallel to the Z-axis is referred to as a Z direction. When various elements are viewed parallel to the Z direction, the appearance is defined as a plan view.

A display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

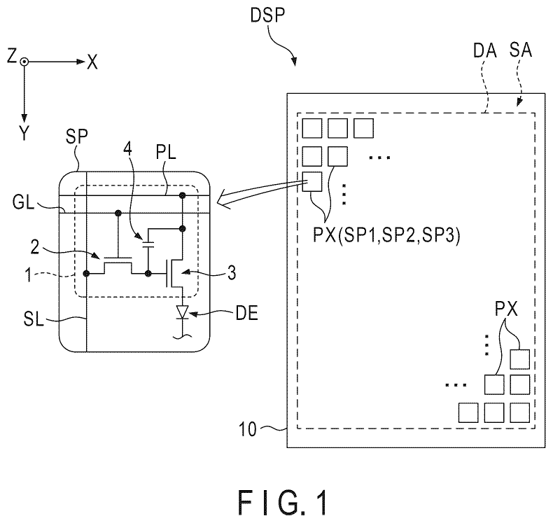

FIG. 1 is a view showing a configuration example of a display device DSP of a present embodiment. The display device DSP comprises an insulating substrate 10. The substrate 10 has a display area DA which displays an image and a surrounding area SA around the display area DA. The substrate 10 may be glass or a resinous film having flexibility.

In the present embodiment, the substrate 10 is rectangular as seen in plan view. The shape of the substrate 10 in plan view is not limited to a rectangle and may be another shape such as a square, a circle or an oval.

The display area DA comprises a plurality of pixels PX arranged in a matrix in the X direction and the Y direction. Each pixel PX includes a plurality of subpixels SP which display different colors. The present embodiment assumes a case where each pixel PX includes a red subpixel SP1, a green subpixel SP2, and a blue subpixel SP3. However, each pixel PX may include a subpixel SP which exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines GL each supplying a scanning signal to the pixel circuit 1 of each subpixel SP, a plurality of signal lines SL each supplying a video signal to the pixel circuit 1 of each subpixel SP, and a plurality of power lines PL. In the example of FIG. 1, the scanning lines GL and the power lines PL extend in the X direction, and the signal lines SL extend in the Y direction.

A gate electrode of the pixel switch 2 is connected to the scanning line GL. A source electrode of the pixel switch 2 is connected to the signal line SL. A drain electrode of the pixel switch 2 is connected to a gate electrode of the drive transistor 3 and the capacitor 4. A source electrode of the drive transistor 3 is connected to the power line PL and the capacitor 4. The drain electrode of the drive transistor 3 is connected to the display element DE.

The configuration of the pixel circuit 1 is not limited to the example of the figure. For example, the pixel circuit 1 may comprise more thin-film transistors and capacitors.

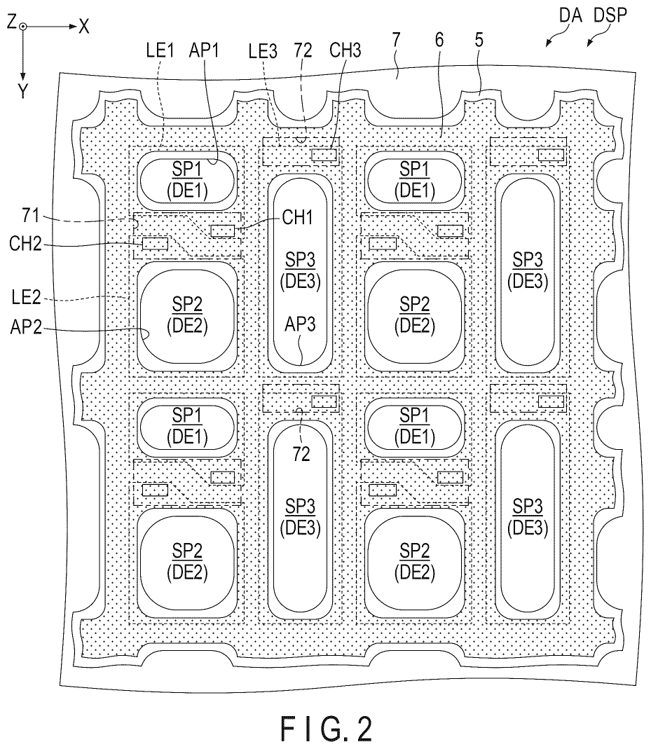

FIG. 2 is a schematic plan view showing a layout example of the subpixels SP1, SP2, and SP3. In the example of FIG. 2, a column in which the subpixels SP1 and SP2 are alternately arranged in the Y direction and a column in which the plurality of subpixels SP3 are repeatedly arranged in the Y direction are formed. These columns are alternately arranged in the X direction.

The layout and the sizes of the subpixels SP1, SP2, and SP3 are not limited to the example of FIG. 2. As another example, the subpixels SP1, SP2, and SP3 may be arranged in the X direction. Further, at least two of the subpixels SP1, SP2, and SP3 may have the same size.

A rib layer 5 is provided in the display area DA. The rib layer 5 includes pixel apertures AP1, AP2, and AP3 (first apertures) in the respective subpixels SP1, SP2, and SP3. In the example of FIG. 2, the pixel aperture AP1 is smaller than the pixel aperture AP2, and the pixel aperture AP2 is smaller than the pixel aperture AP3. Thus, among the subpixels SP1, SP2, and SP3, the subpixel SP1 has the smallest aperture ratio, and the subpixel SP3 has the greatest aperture ratio.

A partition 6 is provided in the display area DA. The partition 6 is located above the rib layer 5 to entirely overlap the rib layer 5. In the example of FIG. 2, the partition 6 has a planar shape similar to that of the rib layer 5. In other words, the partition 6 includes an aperture in each of the subpixels SP1, SP2, and SP3. From another viewpoint, the partition 6 has a grating shape as seen in plan view and surrounds each of the pixel apertures AP1, AP2, and AP3.

The subpixel SP1 includes a display element DE1 including a lower electrode LE1, which overlaps the pixel aperture AP1. The subpixel SP2 includes a display element DE2 including a lower electrode LE2, which overlaps the pixel aperture AP2. The subpixel SP3 includes a display element DE3 including a lower electrode LE3, which overlaps the pixel aperture AP3. The lower electrodes LE1, LE2, and LE3 are spaced apart from one another.

The pixel circuits 1 (shown in FIG. 1) of the subpixels SP1, SP2, and SP3 are provided below the respective lower electrodes LE1, LE2, and LE3. The lower electrode LE1 is connected to the pixel circuit 1 of the subpixel SP1 through a contact hole CH1 (a first contact hole). The lower electrode LE2 is connected to the pixel circuit 1 of the subpixel SP2 through a contact hole CH2 (a second contact hole). The lower electrode LE3 is connected to the pixel circuit 1 of the subpixel SP3 through a contact hole CH3.

An inorganic insulating layer 7 is provided in the display area DA. The inorganic insulating layer 7 is located below the rib layer 5 and the partition 6. The inorganic insulating layer 7 overlaps the pixel apertures AP1, AP2, and AP3 in plan view.

The inorganic insulating layer 7 includes apertures 71 and 72 (second apertures). The apertures 71 and 72 overlap the rib layer 5 and the partition 6 in plan view. The aperture 71 is located between the pixel aperture AP1 and the pixel aperture AP2 in the Y direction. The aperture 72 is provided between two pixel apertures AP3 adjacent to each other in the Y direction. The contact holes CH1 and CH2 overlap the aperture 71 in plan view. The contact hole CH3 overlaps the aperture 72 in plan view.

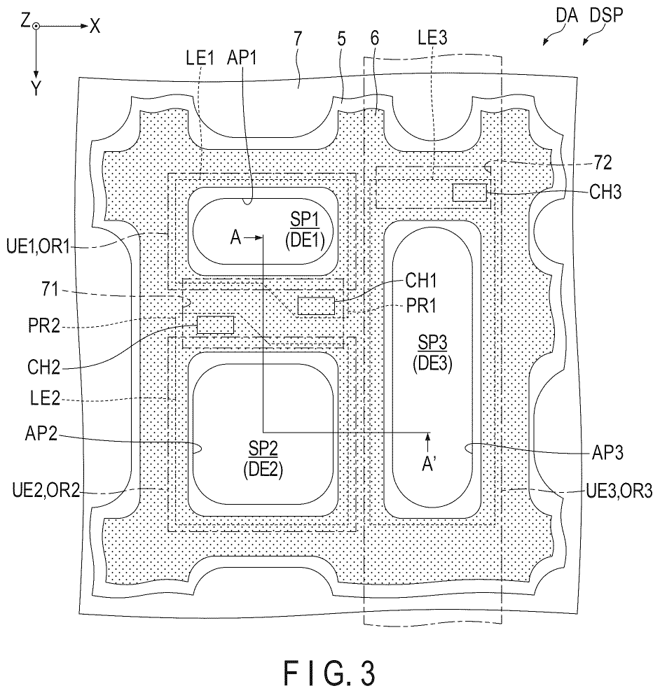

FIG. 3 is a schematic plan view showing the subpixels SP1, SP2, and SP3 shown in FIG. 2 in an enlarged manner. The display element DE1 of the subpixel SP1 further includes an upper electrode UE1 and an organic layer OR1 that overlap the pixel aperture AP1. The display element DE2 of the subpixel SP2 further includes an upper electrode UE2 and an organic layer OR2 that overlap the pixel aperture AP2. The display element DE3 of the subpixel SP3 further includes an upper electrode UE3 and an organic layer OR3 that overlap the pixel aperture AP3. The upper electrodes UE1, UE2, and UE3 and the organic layers OR1, OR2, and OR3 overlap the inorganic insulating layer 7 in plan view.

In the example of FIG. 3, the lower electrode LE1 has a protrusion portion PR1 (a first protrusion portion) having a protrusion shape extending to the lower electrode LE2, and the lower electrode LE2 has a protrusion portion PR2 (a second protrusion portion) having a protrusion shape extending to the lower electrode LE1. The protrusion portions PR1 and PR2 overlap the aperture 71 in plan view. The contact holes CH1 and CH2 overlap the protrusion portions PR1 and PR2, respectively in plan view. The lower electrodes LE1 and LE2 may not include the respective protrusion portions PR1 and PR2. In addition, the lower electrode LE3 may include a protrusion portion overlapping the contact hole CH3 in plan view.

In the example of FIG. 3, the outer shapes of the lower electrodes LE1, LE2, and LE3 are indicated by dotted lines, and the outer shapes of the organic layers OR1, OR2, and OR3 and the upper electrodes UE1, UE2, and UE3 are indicated by one-dot chain lines. The outer shapes of the respective lower electrodes, organic layers, and upper electrodes shown in the figure may not reflect the exact shapes.

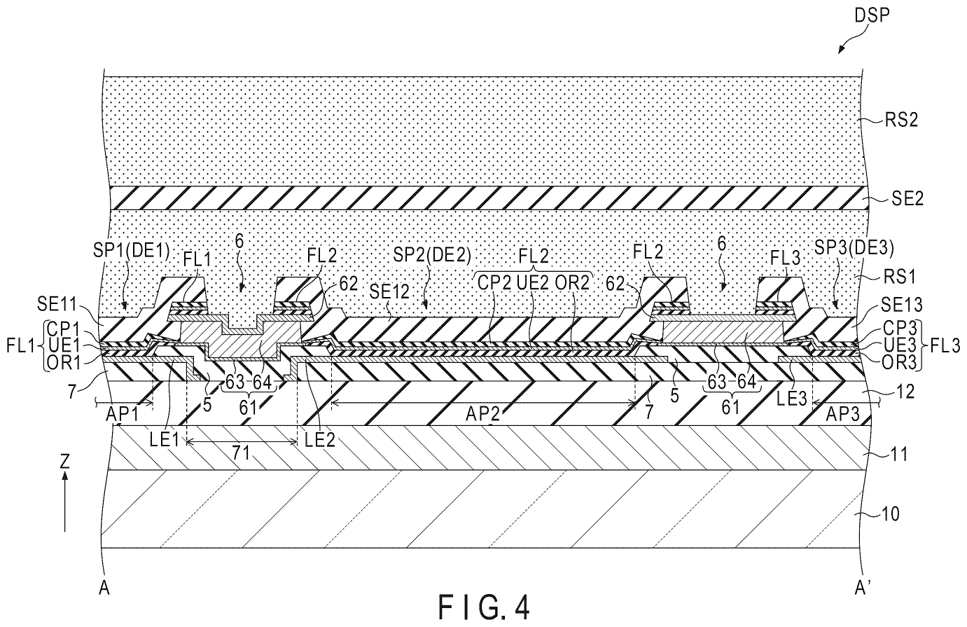

FIG. 4 is a schematic cross-sectional view showing the display device DSP along A-A′ line in FIG. 3. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is provided below an organic insulating layer 12 and is covered with the organic insulating layer 12. The organic insulating layer 12 functions as a planarization film which planarizes irregularities formed by the circuit layer 11.

The lower electrodes LE1, LE2, and LE3 are provided above the organic insulating layer 12. The inorganic insulating layer 7 is provided between the organic insulating layer 12 and the lower electrodes LE1, LE2, and LE3. The lower electrodes LE1 and LE2 abut the organic insulating layer 12 in the aperture 71. The inorganic insulating layer 7 is thicker than the lower electrodes LE1, LE2, and LE3.

The rib layer 5 is provided on the organic insulating layer 12, the inorganic insulating layer 7, and the lower electrodes LE1, LE2, and LE3. The rib layer 5 abuts the organic insulating layer 12 between the lower electrode LE1 and the lower electrode LE2 and abuts the inorganic insulating layer 7 between the lower electrode LE2 and the lower electrode LE3. End portions of the lower electrodes LE1, LE2, and LE3 are covered with the rib layer 5.

The partition 6 includes a conductive lower portion 61 provided on the rib layer 5 and an upper portion 62 provided on the lower portion 61. The upper portion 62 has a width greater than that of the lower portion 61. This configuration allows the both end portions of the upper portion 62 to protrude relative to the respective side surfaces of the lower portion 61. This shape of the partition 6 is called an overhang shape.

In the example of FIG. 4, the lower portion 61 includes a conductive bottom layer 63 provided on the rib layer 5 and a stem layer 64 provided on the bottom layer 63. For example, the bottom layer 63 is thinner than the stem layer 64. In the example of FIG. 4, the both end portions of the bottom layer 63 protrude relative to the respective side surfaces of the stem layer 64. The aperture 71 overlaps the bottom layer 63 in plan view.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 abut the side surfaces of the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of light beams emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

A part of the stacked film FL1 is located on the upper portion 62. This part is spaced apart from a part that is located around the partition 6 of the stacked film FL1 (in other words, from the part which constitutes the display element DE1). Similarly, a part of the stacked film FL2 is located on the upper portion 62. This part is spaced apart from a part that is located around the partition 6 of the stacked film FL2 (in other words, from the part which constitutes the display element DE2). Similarly, a part of the stacked film FL3 is located on the upper portion 62. This part is spaced apart from a part that is located around the partition 6 of the stacked film FL3 (in other words, from the part which constitutes the display element DE3).

Sealing layers SE11, SE12, and SE13 are provided in the subpixels SP1, SP2 and SP3, respectively. The sealing layer SE11 continuously covers the cap layer CP1 and the partition 6 around the subpixel SP1. The sealing layer SE12 continuously covers the cap layer CP2 and the partition 6 around the subpixel SP2. The sealing layer SE13 continuously covers the cap layer CP3 and the partition 6 around the subpixel SP3.

In the example of FIG. 4, the stacked film FL1 and the sealing layer SE11 located on the partition 6 between the subpixels SP1 and SP2 are spaced apart from the stacked film FL2 and the sealing layer SE12 located on this partition 6. The stacked film FL2 and the sealing layer SE12 located on the partition 6 between the subpixels SP2 and SP3 are spaced apart from the stacked film FL3 and the sealing layer SE13 located on this partition 6.

The sealing layers SE11, SE12, and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film, or a cover glass may be further provided above the resin layer RS2. Such a cover member may be attached to the resin layer RS2 via, for example, an adhesive layer such as an optical clear adhesive (OCA).

The organic insulating layer 12 is composed of an organic insulating material such as polyimide. Each of the rib layer 5, the inorganic insulating layer 7, and the sealing layers SE11, SE12, SE13, and SE2 is composed of an inorganic insulating material such as silicon nitride (SiNx), silicon oxide (SiOx), silicon oxynitride (SiON), or aluminum oxide (Al₂O₃). As an example, the inorganic insulating layer 7 is composed of the same material as the rib layer 5. Each of the resin layers RS1 and RS2 is composed of, for example, a resinous material (organic insulating materials) such as epoxy resins or acrylic resins.

Each of the lower electrodes LE1, LE2, and LE3 has a reflective layer composed of, for example, silver, and a pair of conductive oxide layers covering the upper and lower surfaces of the reflective layer. Each of the conductive oxide layers can be composed of, for example, a transparent conductive oxide such as indium tin oxide (ITO), indium zinc oxide (IZO), or indium gallium zinc oxide (IGZO).

The upper electrodes UE1, UE2, and UE3 are composed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is composed of a plurality of thin films including a light emitting layer. As an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z direction. The organic layers OR1, OR2, and OR3 each may comprise other structures such as a tandem structure including a plurality of light emitting layers.

For example, the cap layers CP1, CP2, and CP3 each comprise a multilayer structure in which a plurality of transparent layers are stacked. These transparent layers may include a layer composed of an inorganic material and a layer composed of an organic material. These transparent layers have different refractive indexes. For example, the refractive indexes of these transparent layers are different from the refractive indexes of the upper electrodes UE1, UE2, and UE3 and the refractive indexes of the sealing layers SE11, SE12, and SE13. At least one of the cap layers CP1, CP2, and CP3 may be omitted.

For example, each of the bottom layer 63 and the stem layer 64 of the partition 6 is composed of a metal material. For a metal material of the bottom layer 63, for example, molybdenum, titanium, titanium nitride (TiN), a molybdenum-tungsten alloy (MoW), or a molybdenum-niobium alloy (MoNb) can be used. For a metal material of the stem layer 64, for example, aluminum (Al), an aluminum-neodymium alloy (AlNd), an aluminum-yttrium alloy (AlY), or an aluminum-silicon alloy (AlSi) can be used. The stem layer 64 may be composed of an insulating material.

For example, the upper portion 62 of the partition 6 includes a stacked layer structure comprising a lower layer composed of a metal material and an upper layer composed of a conductive oxide. For a metal material forming the lower layer, for example, titanium, titanium nitride, molybdenum, tungsten, a molybdenum-tungsten alloy, or a molybdenum-niobium alloy may be used. For a conductive oxide forming the top layer, for example, ITO or IZO may be used. The upper portion 62 may comprise a single-layer structure of a metal material. The upper portion 62 may further include a layer composed of an insulating material.

A common voltage is applied to the partition 6. This common voltage is applied to each of the upper electrodes UE1, UE2, and UE3 in contact with the side surfaces of the lower portion 61. The lower electrodes LE1, LE2, and LE3 each are supplied with pixel voltages according to the video signals of the signal lines SL through the pixel circuits 1 provided in the respective subpixels SP1, SP2, and SP3.

The organic layers OR1, OR2, and OR3 emit light beams in response to the application of a voltage. More specifically, when a potential difference is formed between the lower electrode LE1 and the upper electrode UE1, the light emitting layer of the organic layer OR1 emits light beams of the red wavelength range. When a potential difference is formed between the lower electrode LE2 and the upper electrode UE2, the light emitting layer of the organic layer OR2 emits light beams of the green wavelength range. When a potential difference is formed between the lower electrode LE3 and the upper electrode UE3, the light emitting layer of the organic layer OR3 emits light beams of the blue wavelength range.

As another example, the light emitting layers of the organic layers OR1, OR2, and OR3 may emit light beams of the same color (for example, white). In this case, the display device DSP may comprise a color filter that converts the light beams emitted from the light emitting layers into light beams of the colors corresponding to those of the subpixels SP1, SP2, and SP3. In addition, the display device DSP may comprise a layer including quantum dots that are excited by the light beams emitted from the light emitting layers to generate the light beams of the colors corresponding to those of the subpixels SP1, SP2, and SP3.

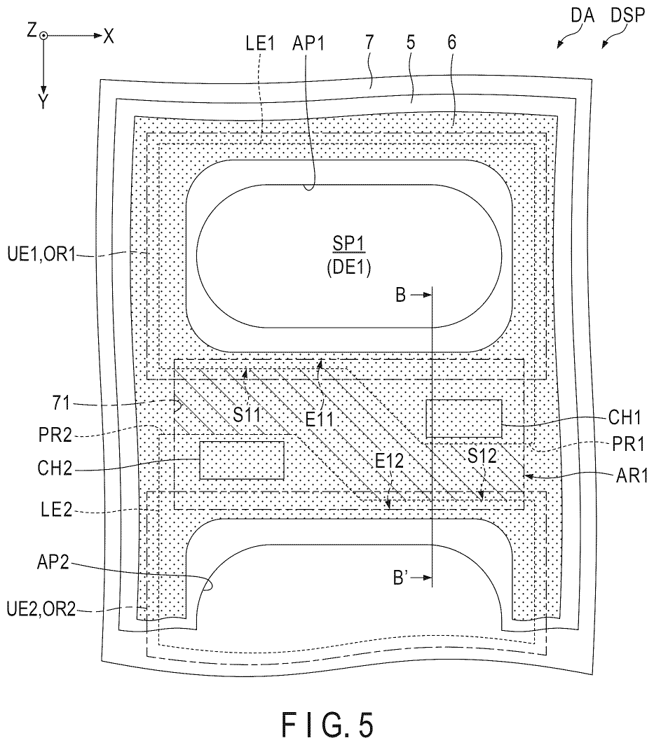

FIG. 5 is a schematic plan view showing the vicinity of the contact holes CH1 and CH2 shown in FIG. 3 in an enlarged manner. As shown in FIG. 5, the display area DA has a first area AR1 corresponding to an area located between the lower electrode LE1 and the lower electrode LE2 and overlapping the aperture 71. That is, the first area AR1 does not overlap the lower electrodes LE1 and LE2 and the inorganic insulating layer 7 in plan view. The partition 6 covers the first area AR1 in plan view. In the example of FIG. 5, the first area AR1 abuts the protrusion portions PR1 and PR2 in plan view. In the example of FIG. 5, the first area AR1 is indicated by hatch lines.

The lower electrode LE1 has a first side S11. The lower electrode LE2 has a second side S12. The first side S11 and the second side S12 extend in the X direction. The first side S11 is located between the pixel aperture AP1 and the contact hole CH2 in the Y direction. In the example shown in FIG. 5, the first side S11 is located between the pixel aperture AP1 and the contact hole CH1 in the Y direction. The second side S12 is located between the pixel aperture AP2 and the contact hole CH1 in the Y direction. In the example shown in FIG. 5, the second side S12 is located between the pixel aperture AP2 and the contact hole CH2 in the Y direction.

The protrusion portion PR1 protrudes from the first side S11 toward the lower electrode LE2 and overlaps the contact hole CH1. The protrusion portion PR2 protrudes from the second side S12 toward the lower electrode LE1 and overlaps the contact hole CH2. In the example of FIG. 5, the protrusion portions PR1 and PR2 each have a trapezoid shape.

The aperture 71 has a first edge portion E11 and a second edge portion E12. The first edge portion E11 extends in the X direction. The second edge portion E12 faces the first edge portion E11 in the Y direction and extends in the X direction.

The first edge portion E11 is located between the contact hole CH1 and the pixel aperture AP1 in the Y direction and overlaps the partition 6 in plan view. In the example shown in FIG. 5, the first edge portion E11 is located between the first side S11 and the pixel aperture AP1 in the Y direction. The second edge portion E12 is located between the contact hole CH2 and the pixel aperture AP2 in the Y direction and overlaps the partition 6 in plan view. In the example shown in FIG. 5, the second edge portion E12 is located between the second side S12 and the pixel aperture AP2 in the Y direction. The first edge portion E11 may be provided between the first side S11 and the contact hole CH1 in the Y direction. The second edge portion E12 may be provided between the second side S12 and the contact hole CH2 in the Y direction.

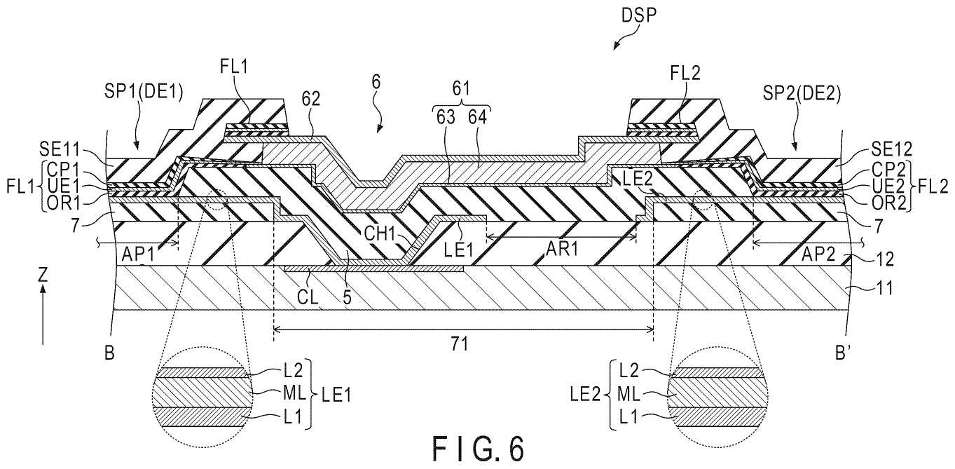

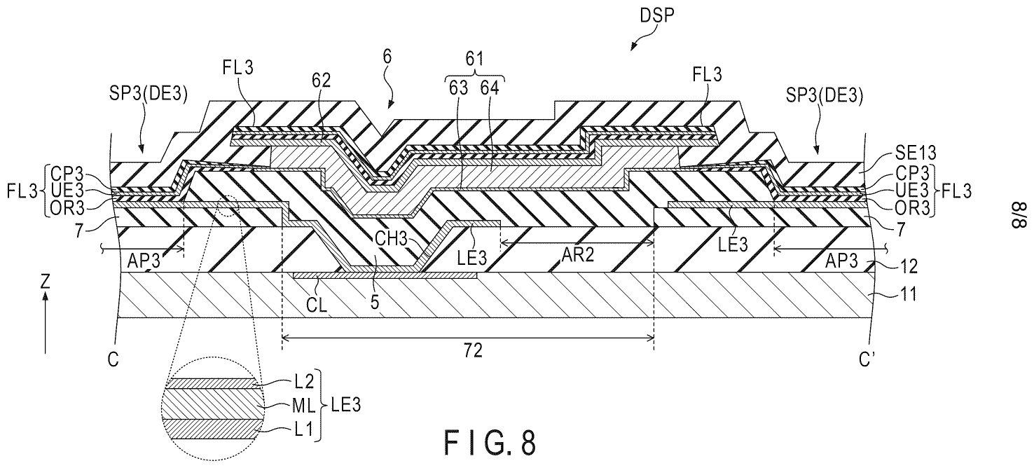

FIG. 6 is a schematic cross-sectional view showing the display device DSP along B-B′ line in FIG. 5. FIG. 6 and FIG. 8 to be described omit the illustration of the substrate 10, the resin layers RS1 and RS2, and the sealing layer SE2 shown in FIG. 4. The rib layer 5 abuts the organic insulating layer 12 in the first area AR1. The bottom layer 63 covers the first area AR1 in plan view.

The contact hole CH1 is provided on the organic insulating layer 12 and penetrates the organic insulating layer 12. The lower electrode LE1 abuts a conductive layer CL included in the circuit layer 11 through the contact hole CH1. The conductive layer CL corresponds to the source electrode or the drain electrode of the drive transistor 3 shown in FIG. 1.

As shown in an enlarged manner in FIG. 6, the lower electrodes LE1 and LE2 each include a metal layer ML, a first layer L1 covering the bottom surface of the metal layer ML and a second layer L2 covering the upper surface of the metal layer ML. For example, the metal layer ML is a reflective layer composed of silver. For example, the first layer L1 and the second layer L2 each are a conductive oxide layer composed of a transparent conductive oxide such as ITO.

For example, the second layer L2 is thinner than each of the first layer L1 and the metal layer ML. The first layer L1 is thinner than the metal layer ML or is as thick as the metal layer ML. The relationship among the thicknesses of the metal layer ML, the first layer L1, and the second layer L2 are not limited to the above examples. For example, the second layer L2 may be thicker than each of the first layer L1 and the metal layer ML.

Though not illustrated, the contact hole CH2 shown in FIG. 5 is provided on the organic insulating layer 12 and penetrates the organic insulating layer 12, similarly to the contact hole CH1. The lower electrode LE2 abuts the conductive layer CL included in the circuit layer 11 through the contact hole CH2.

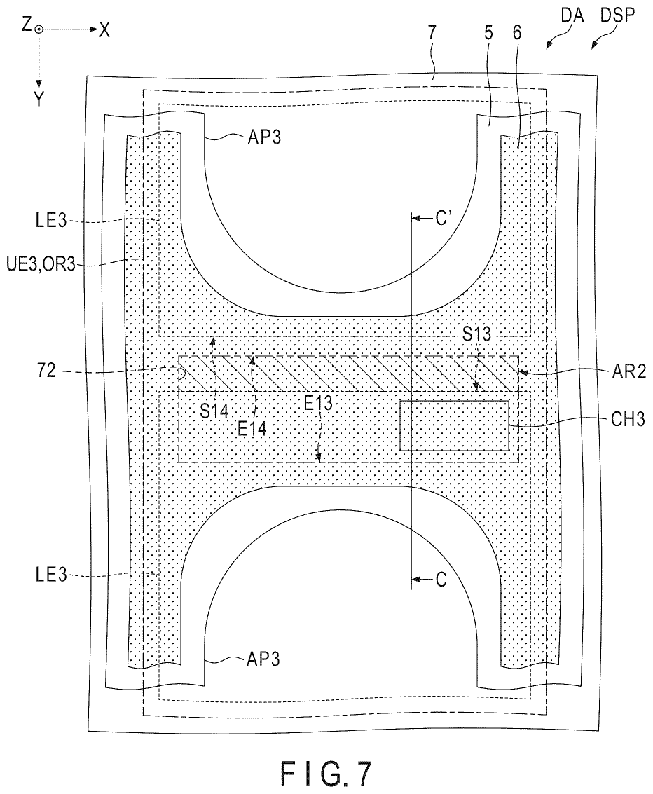

FIG. 7 is a schematic plan view showing the vicinity of the contact hole CH3 shown in FIG. 3 in an enlarged manner. As shown in FIG. 7, the display area DA has a second area AR2, which corresponds to an area located between two lower electrodes LE3 adjacent to each other in the second direction Y and overlapping the aperture 72. That is, the second area AR2 does not overlap the lower electrode LE3 and the inorganic insulating layer 7. The partition 6 covers the second area AR2 in plan view. In the example of FIG. 7, the second area AR2 is indicated by hatch lines.

The lower electrode LE3 has a third side S13 and a fourth side S14. The third side S13 and the fourth side S14 extend in the X direction. The third side S13 corresponds to a side on which the contact hole CH3 is located, among sides constituting the lower electrode LE3. The fourth side S14 corresponds to a side located on the opposite side of the third side S13 with respect to the pixel aperture AP3 in the Y direction.

The aperture 72 has a third edge portion E13 and a fourth edge portion E14. The third edge portion E13 extends in the X direction. The fourth edge portion E14 faces the third edge portion E13 in the Y direction and extends in the X direction.

The third edge portion E13 is located between the contact hole CH3 and the pixel aperture AP3 in the Y direction and overlaps the partition 6 in plan view. In the example shown in FIG. 7, the third edge portion E13 is located between the third side S13 and the pixel aperture AP3 in the Y direction. The fourth edge portion E14 overlaps the partition 6 in plan view. In the example shown in FIG. 7, the fourth edge portion E14 is located between the third side S13 and the fourth side S14 in the Y direction. The third edge portion E13 may be located between the third side S13 and the fourth side S14 in the Y direction. The fourth edge portion E14 may be located between the fourth side S14 and the pixel aperture AP3 in the Y direction.

FIG. 8 is a schematic cross-sectional view showing the display device DSP along C-C′ line in FIG. 7. The lower electrode LE3 abuts the organic insulating layer 12 in the aperture 72. The aperture 72 overlaps the bottom layer 63 of the partition 6 in plan view. The rib layer 5 abuts the organic insulating layer 12 in the second area AR2. The bottom layer 63 covers the second area AR2 in plan view.

The contact hole CH3 is provided on the organic insulating layer 12 and penetrates the organic insulating layer 12. The lower electrode LE3 abuts the conductive layer CL included in the circuit layer 11 through the contact hole CH3.

Similarly to the lower electrodes LE1 and LE2, the lower electrode LE3 includes the metal layer ML, the first layer L1 covering the bottom surface of the metal layer ML, and the second layer L2 covering the upper surface of the metal layer ML.

In the present embodiment, the inorganic insulating layer 7 is provided between the organic insulating layer 12 and the respective lower electrodes LE1, LE2, and LE3. For example, a display device DSP that comprises no inorganic insulating layer 7 and has a portion overlapping the pixel aperture AP1 and having a defective such as a pinhole, of the lower electrode LE1, may cause moisture contained in the organic insulating layer 12 to enter the organic layer OR1 through the defectiveness. The organic layer OR1 typically has low moisture resistances. Moisture entering the organic layer OR1 may cause display failures.

In contrast, the present embodiment includes the inorganic insulating layer 7 that can suppress the entrance of moisture into the defective, for example, even when the portion overlapping the pixel aperture AP1, of the lower electrode LE1, has a defective such as a pinhole. This can suppress display failures and degradation in display quality in the display device DSP.

In the present embodiment, the apertures 71 and 72 of the inorganic insulating layer 7 each overlap the rib layer 5 composed of an inorganic material. Thus, the rib layer 5 suppresses the entrance of moisture into the organic layers OR1, OR2, and OR3 through the apertures 71 and 72. This can suppress display failures and degradation in display quality in the display device DSP.

An example of a manufacturing method of the display device DSP performs patterning on the lower electrodes LE1, LE2, and LE3 and then performs heat-treatment to crystallize ITO contained in the second layer L2 of the lower electrodes LE1, LE2, and LE3. The heat-treatment allows the organic insulating layer 12 to have a high temperature and to evaporate moisture contained therein.

The present embodiment has the first area AR1 and the second area AR2, which do not overlap the lower electrodes LE1, LE2, and LE3 and the inorganic insulating layer 7. Moisture evaporated in this heat-treatment passes through the first area AR1 and the second area AR2 and then is released to the atmosphere. This reduces the amount of moisture in the organic insulating layer 12, further suppressing display failures caused by the moisture.

The present embodiment has the rib layer 5 abutting the organic insulating layer 12 in the first area AR1 and the second area AR2. Thus, the rib layer 5 suppresses the entrance of moisture to the organic layers OR1, OR2, and OR3 through the first area AR1 and the second area AR2. This can suppress display failures and degradation in display quality in the display device DSP.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
an organic insulating layer composed of an organic material;
a first lower electrode provided above the organic insulating layer;
an inorganic insulating layer composed of an inorganic material and provided between the organic insulating layer and the first lower electrode;
a rib layer including a first aperture overlapping the first lower electrode; wherein
the inorganic insulating layer overlaps the first aperture in plan view.

2. The display device of claim 1, wherein
the inorganic insulating layer has a second aperture overlapping the rib layer in plan view.

3. The display device of claim 2, further comprising:
a partition including a lower portion provided above the rib layer and an upper portion having an end portion protruding relative to a side surface of the lower portion, wherein
the second aperture overlaps the partition in plan view.

4. The display device of claim 3, wherein
the lower portion includes:
a bottom layer having conductivity and provided on the rib layer; and
a stem layer provided on the bottom layer, and
the second aperture overlaps the bottom layer in plan view.

5. The display device of claim 2, further comprising:
a pixel circuit provided below the organic insulating layer, wherein
the first lower electrode is connected to the pixel circuit through a first contact hole provided in the organic insulating layer, and
the first contact hole overlaps the second aperture in plan view.

6. The display device of claim 2, further comprising:
a second lower electrode spaced apart from the first lower electrode, wherein
the inorganic insulating layer is further provided between the organic insulating layer and the second lower electrode, and
the rib layer abuts the organic insulating layer between the first lower electrode and the second lower electrode.

7. The display device of claim 6, further comprising:
an area located between the first lower electrode and the second lower electrode and overlapping the second aperture, wherein
the rib layer abuts the organic insulating layer in the area.

8. The display device of claim 7, further comprising:
a partition including a lower portion provided above the rib layer and an upper portion having an end portion protruding relative to a side surface of the lower portion, wherein
the partition covers the area in plan view.

9. The display device of claim 8, wherein
the lower portion includes:
a bottom layer having conductivity and provided on the rib layer; and
a stem layer provided on the bottom layer, wherein
the bottom layer covers the area in plan view.

10. The display device of claim 6, wherein
the first lower electrode includes a first protrusion portion having a protrusion shape extending to the second lower electrode, and
the first protrusion portion overlaps the second aperture in plan view.

11. The display device of claim 10, further comprising:
a pixel circuit provided below the organic insulating layer, wherein
the first lower electrode is connected to the pixel circuit through a first contact hole provided in the organic insulating layer, and
the first contact hole overlaps the first protrusion portion and the second aperture in plan view.

12. The display device of claim 11, wherein
the second lower electrode includes a second protrusion portion having a protrusion shape extending to the first lower electrode, and
the second protrusion portion overlaps the second aperture in plan view.

13. The display device of claim 12, wherein
the second lower electrode is connected to the pixel circuit through a second contact hole provided in the organic insulating layer, and
the second contact hole overlaps the second protrusion portion and the second aperture in plan view.

14. The display device of claim 13, further comprising:
an area located between the first lower electrode and the second lower electrode and overlapping the second aperture, wherein
the first protrusion portion and the second protrusion abut the area.

15. The display device of claim 1, further comprising:
an organic layer covering the first lower electrode through the first aperture and including a light emitting layer; and
an upper electrode covering the organic layer, wherein
the organic layer and the upper electrode overlap the inorganic insulating layer in plan view.

16. The display device of claim 1, wherein
the inorganic insulating layer is thicker than the first lower electrode.

17. The display device of claim 1, wherein
the first lower electrode includes a layer composed of ITO.

18. The display device of claim 1, wherein
the inorganic insulating layer is composed of the same material as that of the rib layer.

19. The display device of claim 1, wherein
the rib layer is composed of silicon nitride or silicon oxynitride.

20. The display device of claim 1, wherein
the inorganic insulating layer is composed of silicon nitride or silicon oxynitride.
